(19) United States
(12) Patent Application Publication
(10) Pub. No.: US 2017/0154780 A1
(43) Pub. Date: Jun. 1, 2017

(54) SUBSTRATE PROCESSING METHOD AND APPARATUS THEREOF

(71) Applicant: Advanced Micro-Fabrication Equipment Inc, Shanghai, Shanghai (CN)

(72) Inventors: Ping Yang, Shanghai (CN); Lei Wan, Shanghai (CN)

(21) Appl. No.: 15/362,754

(22) Filed: Nov. 28, 2016

(30) Foreign Application Priority Data
Nov. 27, 2015 (CN) 201510840215.9

(51) Int. Cl. H01L 21/3065; H01J 37/32; H01L 21/66

(52) U.S. Cl. CPC H01L 21/3065; H01L 22/12; H01L 22/20; H01J 37/3244; H01J 37/32495; H01J 37/32642; H01J 37/32862; H01J 2237/3341

(57) ABSTRACT

The invention relates to a substrate processing method and relevant apparatus. The method includes: placing the substrate into a reactor consist by several walls; delivering etching gas to the reactor to etch the substrate; receiving optical signal from the reactor with the inspection window arranged on at least one of said walls to determine the endpoint of etching; generating protective gas flow in the inspection window during etching process, to prevent or reduce the etching gas or etching by-product flow toward the inspection window. This invention could improve the accuracy and stability of etching endpoint detection.

### RELATED APPLICATION

This application claims priority benefit from Chinese Patent Application No. 201510840215.9, filed on Nov. 27, 2015, the entire content of which is incorporated herein by reference.

### FIELD OF INVENTION

This invention relates to semiconductor processing field, especially relevant to a substrate processing method and apparatus thereof which improves the accuracy of etching endpoint determination.

### BACKGROUND OF INVENTION

IC fabrication process is a plane fabrication process which integrates technologies such as photolithography, etching, and deposition, ion implantation, to fabricate various complex components in the same substrate and connect such components to fully realize their designed functions. Any error in any process would cause the performance parameter of the circuit deviate from the designed value. At present, the critical dimension of VLSIC (very large scale integrated circuit) decreases as the integration degree improve continuously, therefore the controlling for each process and the accuracy of process result should meet with higher technical requirements.

Taking the etching process for instance, etching process is applied in IC fabrication to produce various etching profiles, such as contact hole/through hole, shallow trench or grid electrode shape etc. One of the common used etching processes is plasma etching (dry etching), the accuracy of etching directly affects the critical dimension of etching profile. Therefore the endpoint controlling in plasma etching has become a key process in plasma etching.

Optical emission spectrometry (OES) is a common method for endpoint detection as this method could be easily integrated in the etching apparatus without affecting the performance of etching, and it implements sensitive detection for any delicate changes in reaction procedure and real-timely provides useful information during etching process.

The purpose of OES is to detect the radiation of plasma in UV/VIS spectrum (200 nm-1100 nm). Determine the plasma element especially the reactive etching substance or etching by-product based on the spectrum of plasma radiation. As the etching material changed, the elements in plasma as well as the radiation spectrum would change in the etching process, especially the etching endpoint. The OES endpoint system could detect the change in spectrum and determine the time when the etching layer has been totally eliminated via continuous monitoring of the plasma radiation.

However the accuracy of OES endpoint detection would decrease gradually as time goes on.

The etching by-product in the course of etching (fluorocarbon gas for instance) would diffuse and deposit at the inner side of inspection window in the common substrate processing apparatus. The etching by-product deposited at the inspection window would absorb the optical signal from plasma (spectrum of certain wave length). The absorption of optical signal would increase as the thickness of by-product increase. However the sensor outside the reactor determines the chemical reaction status based on the optical signal received from the inspection window, thus to determine the etching endpoint promptly and accurately. The intensity of optical signal detected at the inspection window would significantly lower than its actual intensity as certain optical signal was absorbed by the etching by-product deposited at the inspection window. The accuracy of endpoint detection would be affected by this deviation.

According to the theory stated by the inventor, the longer time the etching process lasts, the thicker the etching by-product deposited at inspection window would be, consequently the accuracy of endpoint detection would be worse. The fabrication practice consists with this inference.

### DETAILED DESCRIPTION OF INVENTION

The invention provides a substrate processing method including:

Placing the substrate into a reactor consisted by several walls;

Delivering etching gas to the reactor to etch the substrate;

Receiving optical signal from the reactor at the inspection window arranged on at least one of said walls to determine the endpoint of etching;

Generating protective gas flow at the inspection window during the etching process, to prevent or reduce the etching gas or etching by-product flow toward the inspection window.

Optional, the protective gas flow is a vertical gas curtain formed at the inspection window during the etching process, to prevent or reduce the etching gas or etching by-product flow toward the inspection window.

Optional, a ring was arranged inside the reactor, and the substrate is surrounded by the ring, the path of protective gas is defined by the wall which the inspection window located and said ring.

Optional, an opening was arranged close to the inspection window in the ring so the sensor could receive optical signal from the reactor at the inspection window.

Optional, the protective gas flow includes argon or helium.

The invention provides a substrate processing apparatus including:

A reactor comprising several walls;

A base arranged inside the reactor to fix the substrate;

Gas showerhead arranged inside the reactor to introduce the gas to the reactor, the space between said gas showerhead and such base is plasma processing region;

Inspection window arranged at least one of said walls of reactor to receive optical signal from the reactor and determine the endpoint of etching process;

A ring arranged inside the reactor, and the plasma processing region is surrounded by the ring, a gap is formed between the wall which the inspection window located and the said ring;

Protective gas inlet which is arranged in said gap to introduce protective gas into said gap.

Optional, an opening close to the inspection window is arranged in the ring so the sensor could receive optical signal from the reactor at the inspection window.

Optional, the protective gas flow includes argon or helium.

Optional, the apparatus further includes:

Protective gas source for providing protective gas;

Inspection window cleaning gas source for providing the inspection window cleaning gas;

Controller which is used to control the protective gas source to provide protective gas into the gap from the protective gas inlet during etching process and control the cleaning gas source to provide cleaning gas to the gap from the protective gas inlet for cleaning the inspection window during cleaning process.

Optional, the cleaning gas flow includes oxygen.

The invention further provides a substrate processing apparatus including:

A reactor comprising several walls;

Base arranged inside the reactor to fix the substrate;

Gas showerhead arranged inside the reactor to introduce the gas to the reactor, the space between said gas showerhead and such base is plasma processing region;

Inspection window arranged on at least one of the said walls in reactor to receive optical signal from the reactor and determine the endpoint of etching;

Protective gas inlet, which is used to introduce protective gas into the said reactor, the protective gas flow across the surface of inspection window, to prevent or reduce the etching gas or etching by-product low toward inspection window.

Optional, the apparatus further includes:

Protective gas source which is used to provide protective gas;

Inspection window cleaning gas source which is used to provide the inspection window cleaning gas;

Controller which is used to control the protective gas source to provide protective gas into the reactor from the protective gas inlet during etching process and control the cleaning gas source to provide cleaning gas to the reactor from the protective gas inlet for cleaning the inspection window during cleaning process.

### BRIEF DESCRIPTION OF THE DRAWINGS

FIG. 1 is the structure diagram of a substrate processing apparatus in the present invention;

FIG. 2 is the structure diagram of an altered apparatus in the present invention;

FIG. 3 is the process flow diagram of a substrate processing method in the present invention;

### DETAILED DESCRIPTION OF THE PREFERRED EMBODIMENTS

In order to make the content of this invention easier to understand, the invention would be further explained together with figures included in the patent application. The invention indeed does not limit to this detailed example, the general alteration acknowledged by technicians in this field also included in this patent claim.

Based on the above acknowledgements and theories, the inventor proposed a new substrate processing apparatus and method, which prevents or reduce the etching by-product flow toward inspection window as well as deposition of etching by-product deposited at the inspection window by generate air flow at the inner surface of inspection window, thus to ensure the accuracy of endpoint detection.

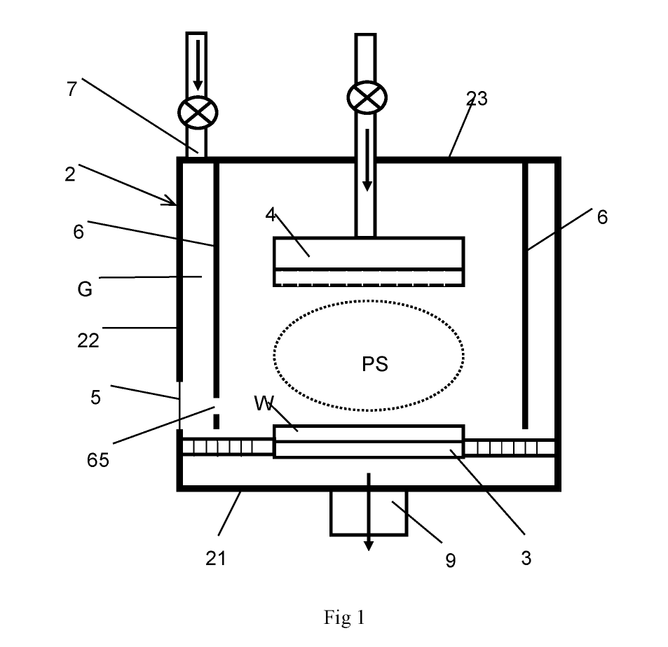

FIG. 1 is the structure diagram of a substrate processing apparatus, said substrate processing apparatus could be a plasma etching apparatus, capacitive coupling plasma apparatus or inductive coupling plasma apparatus for instance. As in FIG. 1, the substrate processing apparatus is consisted by reactor 2 constructed by several walls 21, 22, 23, and wall 21 is bottom wall, wall 22 is side wall, wall 23 is top wall. The base 3 to fix the substrate W and gas showerhead 4 to introduce the etching gas to the reactor 2 were arranged inside the reactor 2, the space PS between the mentioned gas showerhead 4 and such base 3 is for plasma processing purpose; The substrate processing apparatus also includes plasma generator which would decompose the etching gas in plasma processing space PS into plasma and radical. Plasma and radical reached the surface of substrate W would etch the substrate W into designed shape. The by-product from the etching process and the etching gas not used in the reaction would be drained out of reactor 2 by pump 9.

Inspection window 5 arranged on the mentioned wall 22 of reactor 2 to receive optical signal from the reactor 2 and determine the endpoint of etching (the point the etching ended). Ring 6 and protection gas inlet 7 were arranged in substrate processing apparatus to prevent or reduce the etching by-product deposited flow toward inspection window 5. Ring 6 is arranged inside the reactor 2, and surrounded the plasma processing space PS (in other words, the plasma processing space PS is inside the ring 6). Gap G is formed between the wall 22 which the inspection window 5 located and the ring 6.

Protective gas inlet 7 was arranged in said gap G to introduce protective gas to such gap G. The protective gas flow includes argon or helium or other inactive gases. The protective gas introduced by protective gas inlet 7 would generate an vertical air flow in the gap G (air curtain or protection coating in other words), such air flow would prevent or reduce the etching by-product flow toward the inspection window 5. In addition, the existence of ring 6 would reduce the etching by-product, or plasma, radical into the inspection window 5.

An opening 65 close to the inspection window 5 could be arranged in the ring 6, the dimension and the location of opening 65 is relative to the angle of the sensor's receiving optical signal from inspection window 5, so that the sensor could receive optical signal from the reactor at the inspection window 5.

There are two gas sources supplied for protection gas inlet 7: Protective gas source for providing protective gas (not noted in the diagram), cleaning gas source for providing the inspection window cleaning gas (not noted in the diagram). The said cleaning gas includes oxygen or other gases that could remove the etching by-product. A controller (not noted in the diagram) is arranged to control the connection status between these two gas sources and the protection gas inlet 7. For instance, the controller could provide protective gas from the protective gas inlet 7 in the etching stage to reduce the by-product deposition at the surface of inspection window 5; provide cleaning gas from the protective gas inlet in the cleaning stage and clean the inspection window 5.

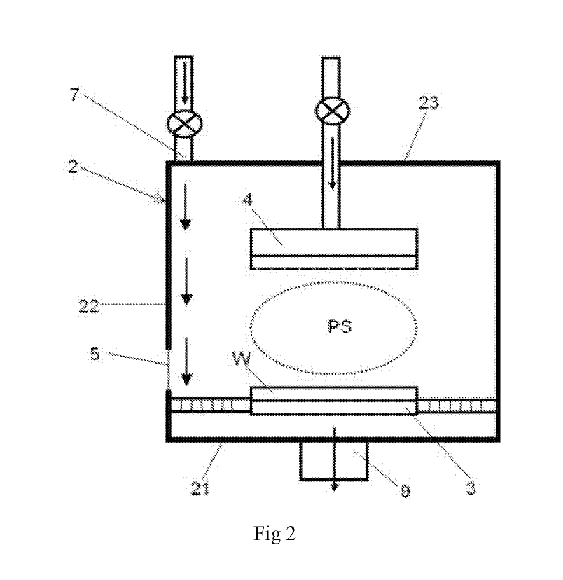

FIG. 2 is the structure diagram of an altered apparatus mentioned in FIG. 1. Except that the apparatus does not consist the ring 6 in FIG. 6, the structure, operation principal as well as the operation process flow of apparatus in FIG. 2 is the same with that in FIG. 1, it is unnecessary to go into details hereafter. In FIG. 2, although there is no component designed to limit the path the protective gas introduced by protective gas inlet 6, the protective gas would be maintained to flow from top to bottom by the wall 22 in the manner of setting the air flow intensity of protective gas (i.e. flow volume of protective gas), and prevent or reduce the etching by-product flow toward inspection window 5, thus to ensure the accuracy and reliability of endpoint detection.

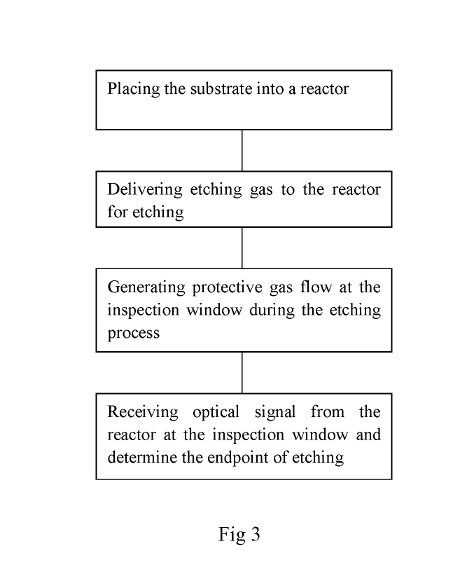

FIG. 3 is the process flow diagram of substrate processing method. The apparatus in FIGS. 1 and 2 could operate following such processing method. The said method mainly includes the following steps:

Placing the substrate into a reactor consisted by several walls;

Delivering etching gas to the reactor to etch the substrate;

Generating protective gas flow at the inspection window during the etching process, to prevent or reduce the etching gas or etching by-product flow toward the inspection window.

Receiving optical signal from the reactor at the inspection window arranged on at least one of said walls to determine the endpoint of etching;

While the instant invention has been shown and described herein in what are conceived to be the most practical and preferred embodiment, it is recognized that the scope of the invention is not to be limited to the details disclosed herein. It is clear that various amendments and modifications to this invention may be made by those skilled in the art after reading the above description of the invention. Therefore the protection scope of this invention shall limited as recited in the appended claims.

1. A substrate processing method including:
placing the substrate into a reactor consisted by several walls;
delivering etching gas to the reactor to etch the substrate;
receiving optical signal from the reactor at the inspection window arranged on at least one of said walls to determine the endpoint of etching;
generating protective gas flow at the inspection window during the etching process, to prevent or reduce the etching gas or etching by-product flow toward the inspection window.

2. The substrate processing method of claim 1, wherein, the protective gas flow is a vertical gas curtain formed at the inspection window during the etching process, to prevent or reduce the etching gas or etching by-product flow toward the inspection window.

3. The substrate processing method of claim 1, wherein, a ring is arranged inside the reactor, and the substrate is surrounded by the ring, the path of protective gas is defined by the wall which the inspection window located and said ring.

4. The substrate processing method of claim 3, wherein, an opening close to the inspection window is arranged in the ring, so that the sensor could receive optical signal from the reactor at the inspection window.

5. The substrate processing method of claim 3, wherein, said protective gas flow includes argon or helium.

6. A substrate processing apparatus including:
a reactor comprising several walls;
a base arranged inside the reactor to fix the substrate;
gas showerhead arranged inside the reactor to introduce the gas to the reactor, the space between said gas showerhead and base is plasma processing region;
inspection window arranged on at least one of said walls in reactor to receive optical signal from the reactor and determine the endpoint of etching process;
a ring arranged inside the reactor, and the plasma processing region is surrounded by the ring, a gap is formed between the wall which the inspection window located and said ring;
protective gas inlet arranged in said gap to introduce protective gas into such gap.

7. The substrate processing apparatus of claim 6, wherein, an opening close to the inspection window is arranged in the ring, the sensor could receive optical signal from the reactor at the inspection window.

8. The substrate processing apparatus of claim 6, wherein, the protective gas flow includes argon or helium.

9. The substrate processing apparatus of claim 6, wherein, the apparatus further including:
protective gas source for providing protective gas;
inspection window cleaning gas source for providing the inspection window cleaning gas;
controller which is used to control the protective gas source to provide protective gas into the gap from the protective gas inlet during etching process, and control the cleaning gas source to provide cleaning gas to the gap from the protective gas inlet for cleaning the inspection window during cleaning process.

10. The substrate processing apparatus of claim 9, wherein, the cleaning gas flow includes oxygen.

11. A substrate processing apparatus which including:
a reactor comprising several walls;
a base arranged inside the reactor to fix the substrate;
gas showerhead arranged inside the reactor to introduce the gas to the reactor, the space between said gas showerhead and such base is plasma processing region;
inspection window arranged on at least one of said walls in reactor to receive optical signal from the reactor and determine the endpoint of etching;
protective gas inlet which is used to introduce protective gas into said reactor, the protective gas flow across the surface of inspection window, to prevent or reduce the etching gas or etching by-product flow toward inspection window.

12. The substrate processing apparatus of claim 11, wherein, the apparatus further includes:
protective gas source which is used to provide protective gas;
inspection window cleaning gas source which is used to provide the inspection window cleaning gas;
controller which is used to control the protective gas source to provide the protective gas to the reactor from the protective gas inlet during etching process, and control the cleaning gas source to provide cleaning gas to the reactor from the protective gas inlet for cleaning the inspection window during cleaning process.
